(19) United States
(12) Patent Application Publication
(10) Pub. No.: US 2008/0081444 A1
(43) Pub. Date: Apr. 3, 2008

(54) Method for forming silicide layer on a silicon surface and its use

(75) Inventor: Chin-Wen Lee, Hsinchu Hsien (TW)

Correspondence Address: NIXON PEABODY LLP - PATENT GROUP, CLINTON SQUARE, P.O. BOX 31051, ROCHESTER, NY, 14603-1051, US

(73) Assignee: Promos Technologies Inc., Hsinchu (TW)

(21) Appl. No.: 11/599,776

(22) Filed: Nov. 14, 2006

(30) Foreign Application Priority Data
Sep. 28, 2006 (TW) 095135976

(51) Int. Cl. H01L 21/44

(52) U.S. Cl. 438/528; 438/682; 438/683; 438/659; 438/586

(57) ABSTRACT

A method for forming a silicide layer on a silicon surface is provided. First, inert gas ions are implanted into the silicon surface. Then, a metal layer is formed on the surface and subsequently converted into the suicide layer. Thereby the resistance of the silicide can be reduced and the uniformity can be raised without substantially altering the doping concentration of conductive component(s). Thus, the efficiency of the semiconductor device can be enhanced.

This application claims priority to Taiwan Patent Application No. 095135976 filed on Sep. 28, 2006.

### CROSS-REFERENCES TO RELATED APPLICATIONS

Not applicable.

### BACKGROUND OF THE INVENTION

1. Field of the Invention

The subject invention relates to a method for forming a silicide layer on a silicon surface. More specifically, the subject invention relates to a method for forming a silicide layer on the surface of a semiconductor device.

2. Descriptions of the Related Art

In the developing semiconductor industry, semiconductor devices have not only integrated circuits, but have also become increasingly smaller. The prior structure of a semiconductor device is no longer suitable for use and is in need of a readjustment and rearrangement for effective performance. Aside from the problematic short channel effect, another problem has resulted from the miniaturization of the device: parasitic resistance. Because resistance has an inversely proportional relationship with the cross section of the conductive line, parasitic resistance increases as the width of the structure decreases with the reduction of the device size.

In general, to promote the performance of a semiconductor device, a silicide layer is usually adopted on a polysilicon layer. In the manufacturing process, parasitic resistance is primarily reduced by a polycide or salicide process (self-aligned silicidation). The salicide process can significantly reduce the contact resistance because a silicide layer can be formed on both the source area and the drain area.

The salicide process consists of many steps. First, source/drain areas on a substrate with a gate structure are formed. Second, a metal layer is deposited using sputtering deposition, and then, a first rapid thermal process (RTP) is conducted to form a silicide layer from the reaction of the metal in the metal layer with the silicon in the substrate. Using an N-type transistor as an example, a substrate with a gate structure is doped with a high concentration of arsenic ions to form source/drain diffusion areas on predetermined source/drain positions. Then, a layer of metal selected from a group consisting of Ti, Co, and Ni is deposited using sputtering deposition. Thereafter, a first RTP is conducted to form a silicide layer from the reaction of the metal in the metal layer with the silicon in the substrate. Third, a selective wet etching process is performed to remove the non-reacted metal layer portion and to leave the silicide layer formed on the surfaces of the gate, the source and the drain. Along with doping the predetermined source/drain positions by a high concentration of arsenic ions, the arsenic ions are normally also doped on the gate as well. The high concentration of arsenic ions on the gate and the source/drain areas will easily lead to an increase of the resistance in the silicide formed afterward and will decrease the uniformity thereof that deteriorates the performance of the device. Therefore, a second RTP is normally performed after the formation of a silicide layer by the first RTP, to reduce the resistance of the silicide layer.

In response to the above-mentioned problems, a method with an additional ion implant step has been disclosed. Taking an N-type transistor as an example, an ion implantation is conducted on the gate and the source/drain areas after the doping of a high concentration of arsenic ions and the anneal processing. The ion implantation may use arsenic ions. Then, the remaining steps of the aforementioned salicide process are conducted. However, this technology still has disadvantages. For example, the arsenic (As) ions are N-type impurities that will result in a decreased doping concentration of P-type transistors after they are implanted thereinto. This is harmful to the entire performance of the integrated circuits.

Thus, it is essential to solve these above-mentioned problems by providing a method that not only reduces the resistance, but also increases the uniformity of the silicide layer without decreasing the doped concentration of the conductive materials.

### SUMMARY OF THE INVENTION

An objective of the subject invention is to provide a method for forming a silicide layer on a silicon surface and a surface of a semiconductor device to effectively reduce the resistance of the silicide layer and increase its uniformity without decreasing the concentration of the conductive materials doped thereinto.

Another objective of the subject invention is to provide a method for forming a silicide layer on a silicon surface and a surface of a semiconductor device so that the silicide layer in a semiconductor wafer is thinner and has better uniformity to promote the process yield and the quality of final products.

To achieve the above-mentioned objectives, the subject invention provides a method for forming a silicide layer on a silicon surface. The method comprises implanting inert gas ions into the silicon surface; forming a metal layer on the surface; and converting the metal layer into a suicide layer.

The subject invention further provides a method for forming a silicide layer on a silicon surface. The method comprises providing a semiconductor device that comprises a gate structure with a silicon surface and a spacer neighboring the gate structure, both located on a silicon substrate; implanting inert gas ions into the silicon surface and the silicon substrate; forming a metal layer covering the silicon surface, the spacer, and the silicon substrate; and converting the metal layer on both the silicon surface and the silicon substrate into a silicide layer.

The detailed technology and preferred embodiments implemented for the subject invention are described in the following paragraphs accompanying the appended figures for people skilled in this field to well appreciate the features of the claimed invention.

### BRIEF DESCRIPTION OF THE DRAWINGS

FIG. 1A depicts a schematic drawing of implanting conductive materials into a silicon surface;

FIG. 1B depicts a schematic drawing of implanting ions into the silicon surface;

FIG. 1C depicts a schematic drawing of forming a metal layer on the silicon surface;

FIG. 1D depicts a schematic drawing of converting the metal layer into a silicide layer;

FIG. 2A depicts a schematic drawing of implanting conductive materials into a surface of a semiconductor device;

FIG. 2B depicts a schematic drawing of implanting ions into the surface of the semiconductor device;

FIG. 2C depicts a schematic drawing of forming a metal layer;

FIG. 2D depicts a schematic drawing of forming a silicide layer on the surface of the semiconductor device; and

FIG. 2E depicts a schematic drawing of removing a portion of the metal layer on the surface of the semiconductor device.

### DESCRIPTION OF THE PREFERRED EMBODIMENT

An embodiment of a manufacturing method will be disclosed in the following description to explain how the problems and the disadvantages of the prior technology are solved by this invention.

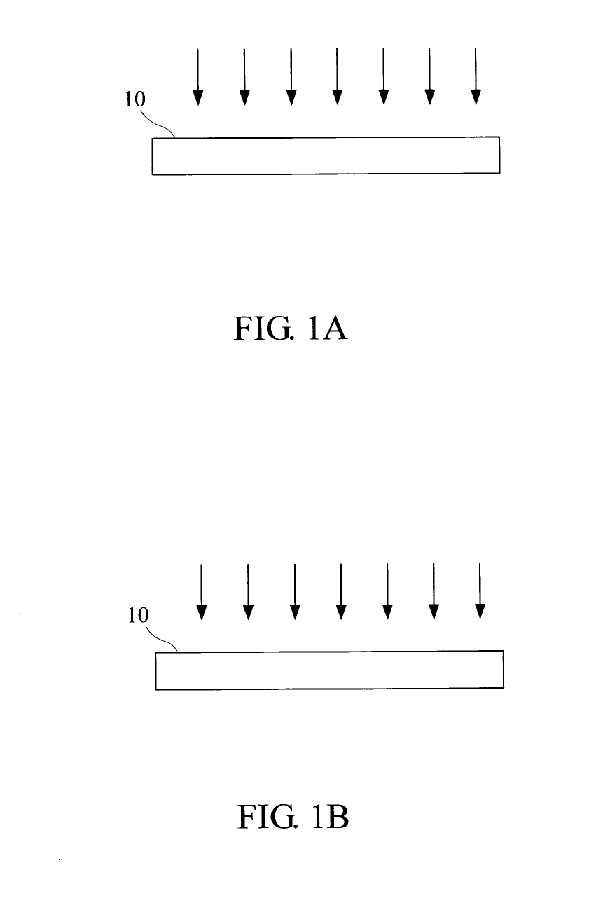

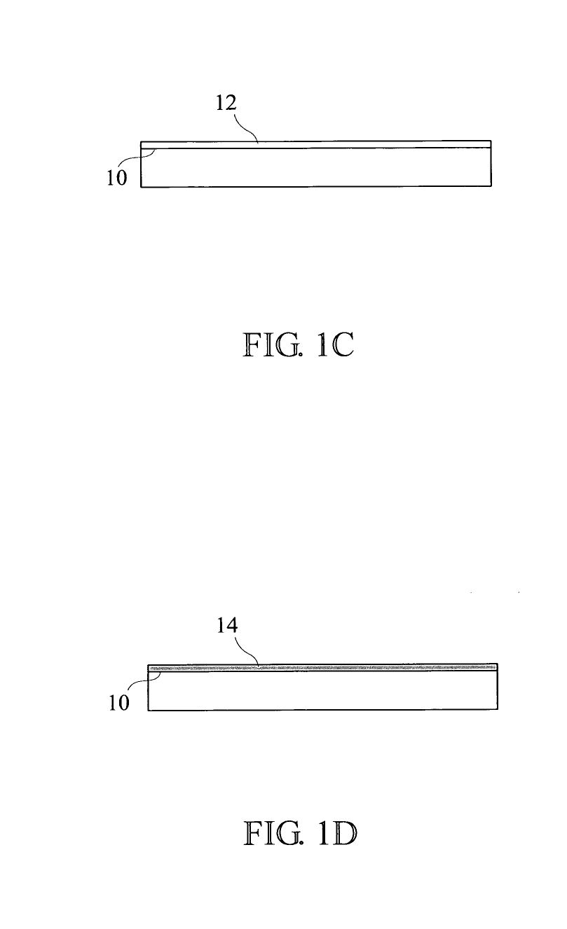

An embodiment of the invention will be disclosed in FIG. 1A to FIG 1D. Please refer to FIG. 1A, where a silicon surface 10 is first provided, and then, conductive materials are implanted onto the silicon surface 10. The conductive materials can be any proper metal materials. Preferably, the conductive materials are selected from a group consisting of As, P, and a combination thereof, or a group consisting of B, BF, and a combination thereof. Specifically, the group consisting of As, P, and a combination thereof is used for an N-type transistor, and the group consisting of B, BF, and a combination thereof is used for a P-type transistor. Taking the N-type transistor as an example, it is preferred that the conductive material is arsenic (As). Next, referring to FIG. 1B, inert gas ions are implanted into the silicon surface 10. Preferably, the inert gas is selected from a group consisting of He, Ne, Ar, Kr, and a combination thereof. More preferably, the inert gas is Ar. Then, referring to FIG. 1C, a cleaning process is performed onto the silicon surface 10, and afterward, titanium and/or titanium nitride is deposited on the silicon surface 10 to form a metal layer 12. Referring to FIG. 1D, a thermal process is performed to convert the metal layer 12 into a silicide layer 14. Next, a wet etching process is performed to remove the non-reacted portion of the metal layer 12.

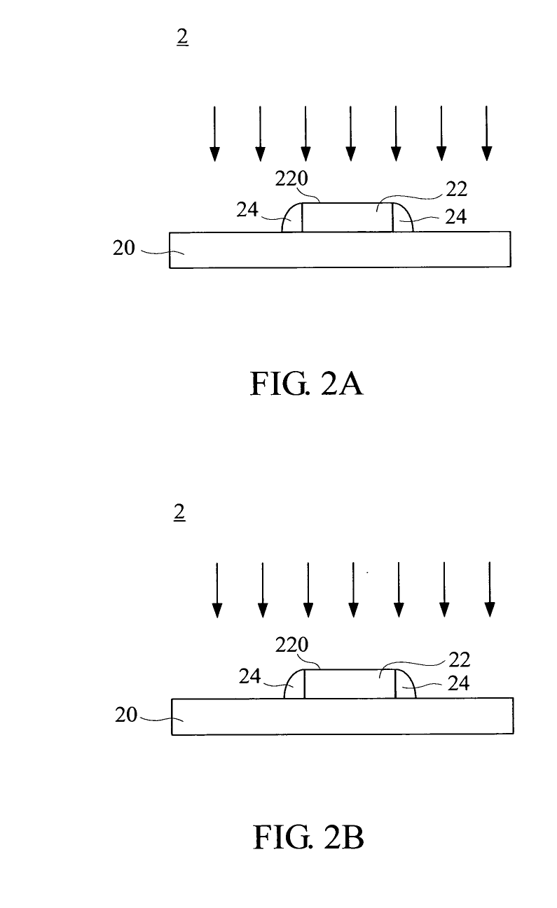

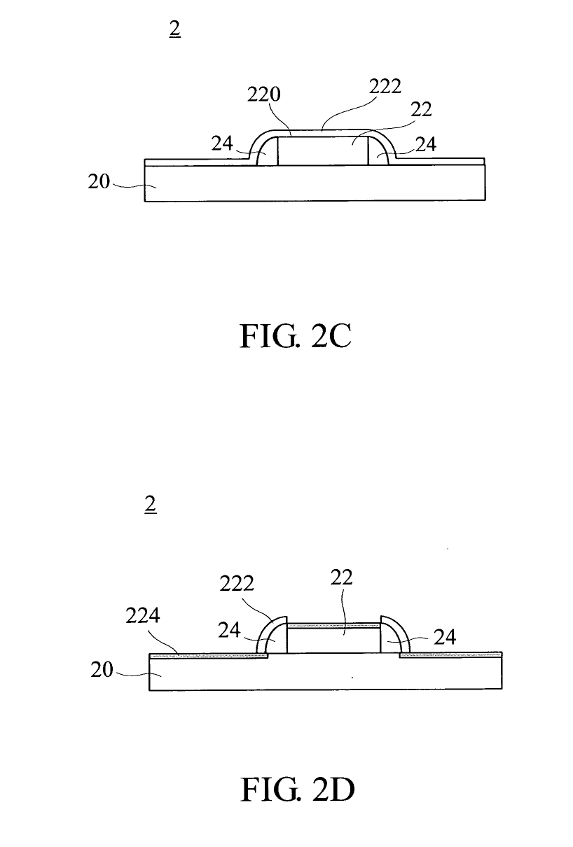

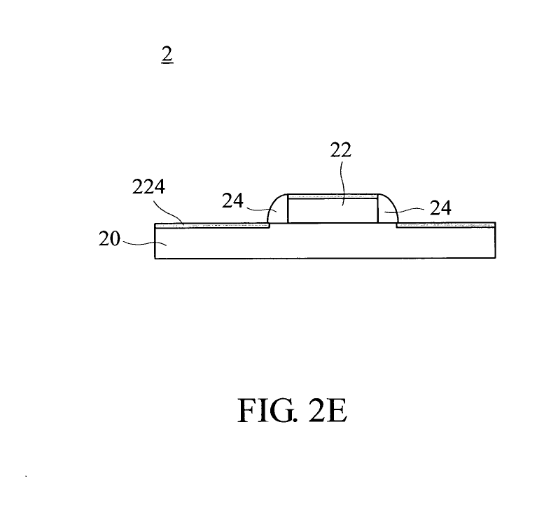

FIG. 2A to FIG. 2E shows another embodiment of the present invention that is applied in a semiconductor device. FIG. 2A illustrates a semiconductor device 2, comprising a gate structure 22 with a silicon surface 220 and a spacer 24 neighboring the gate structure 22, wherein the gate structure 22 and the spacer 24 are formed on a silicon substrate 20. As depicted by the arrow direction shown in FIG. 2A, conductive materials are implanted into the silicon surface 220 and the silicon substrate 20. Similarly, the conductive materials are selected from a group consisting of As, P, and a combination thereof, or a group consisting of B, BF, and a combination thereof. Specifically, for an N-type transistor, arsenic is preferred. Optionally, after the above-mentioned processes, an anneal process such as a RTA process is performed.

Next, please refer to FIG. 2B, inert gas ions are implanted into the silicon surface 220 and the silicon substrate 20 as the arrow direction shows in FIG. 2B. The inert gas is selected from a group consisting of He, Ne, Ar, Kr, and a combination thereof. More preferably, the inert gas is Ar.

Referring to FIG. 2C, a cleaning process is optionally performed onto the silicon surface 220 and the silicon substrate 20. Next, a metal layer 222 is formed to cover the silicon surface 220, the spacer 24 and a portion of the silicon substrate 20. In general, a sputtering deposition is adopted. In an embodiment, a DC (direct current) sputtering method, collimator method, long throw method, ionized PVD method, and etc., can be used to deposit titanium and/or titanium nitride to provide the metal layer 222.

Referring to FIG. 2D, a thermal process is performed. In general, the thermal process is a rapid thermal process, such as a rapid thermal annealing (RTA) process, so that the metal in the portion of the metal layer 222 both on the silicon surface 220 and the silicon substrate 20 can react with silicon to generate silicide, that is, to convert the portion of the metal layer 222 into a silicide layer 224. In view of the silicon substrate 20, the silicide layer 224 is formed on a source/drain area. More specifically, the rapid thermal process increases the temperature quickly to a high level of about 600 to 700° C. and is conducted in the presence of nitrogen.

Next, referring to FIG. 2E, a wet etching process is performed to remove the portion of the metal layer 222 which covers the spacer 24 (i.e. the non-reacted portion of the metal layer 222). In general, an acid solution is often adopted for this wet etching process. The portion of the surface which has converted into TiN but not into TiSi₂ can be removed by for example, but not limited to, a mixture of NH₄OH, H₂O₂, and H₂O or a mixture of H₂SO₄ and H₂O₂. Lastly, a rapid thermal process is performed again to further reduce the resistance of the silicide. Such second rapid thermal process can be performed under a temperature of such as, but not limited to, about 800 to 900° C.

The method of adopting an inert gas process before the formation of a silicide layer in the subject invention can effectively reduce the resistance of the silicide layer. For example, in a real operation that As ions were dopted with an energy of 20 KeV and at a concentration of 3E15, it is found that the resistance of the silicide layer formed by the method of the subject invention is approximately 50% less than that formed by the prior art method without the aforementioned inert gas process.

To sum up, the semiconductor device manufactured by the method according to the subject invention can effectively reduce the resistance of the silicide layer without any change in the concentration of the conductive materials doped thereinto. Moreover, it is noted from the optical measurement that the method of the subject invention can promote the resistance uniformity of the silicide layer. That is, the method of the subject invention can both increase the performance and the integration of semiconductor devices.

The above examples are only intended to illustrate the principle and efficacy of the subject invention, not to limit the subject invention. Any people skilled in this field may proceed with modifications and changes to the above examples without departing from the technical principle and spirit of the subject invention. Therefore, the scope of protection of the subject invention is covered in the following claims as appended.

What is claimed is:

1. A method for forming a silicide layer on a silicon surface comprising:
implanting inert gas ions into the silicon surface;
forming a metal layer on the silicon surface; and
converting the metal layer into a silicide layer.

2. The method of claim 1, further comprising a step of implanting a conductive material into the silicon surface before the implantation of the inert gas ions.

3. The method of claim 2, wherein the conductive material is selected from a group consisting of As, P, and a combination thereof.

4. The method of claim 2, wherein the conductive material is selected from a group consisting of B, BF, and a combination thereof.

5. The method of claim 1, wherein the inert gas is selected from a group consisting of He, Ne, Ar, Kr, and a combination thereof.

6. The method of claim 1, further comprising a step of cleaning the silicon surface before the formation of the metal layer.

7. The method of claim 1, wherein the step of forming the metal layer comprises depositing a titanium and/or titanium nitride layer.

8. The method of claim 1, wherein the step of converting the metal layer into the silicide layer comprises a step of thermal processing.

9. The method of claim 1, further comprising a step of wet etching after the step of converting the metal layer into the silicide layer.

10. A method for forming a silicide layer on a surface in a semiconductor device, the semiconductor device comprising a gate structure with a silicon surface and a spacer neighboring the gate structure, both formed on a silicon substrate, the method comprising:
implanting inert gas ions into the silicon surface and the silicon substrate;
forming a metal layer covering the silicon surface, the spacer, and the silicon substrate; and
converting the metal layer on both the silicon surface and the silicon substrate into a silicide layer.

11. The method of claim 10, further comprising a step of implanting a conductive material into the silicon surface and the silicon substrate before the implantation of the inert gas ions.

12. The method of claim 11, wherein the conductive material is selected from a group consisting of As, P, and a combination thereof.

13. The method of claim 11, wherein the conductive material is selected from a group consisting of B, BF, and a combination thereof.

14. The method of claim 11, wherein the inert gas ions are selected from a group consisting of He, Ne, Ar, Kr, and a combination thereof.

15. The method of claim 11, further comprising a step of cleaning the silicon surface and the silicon substrate before the formation of the metal layer.

16. The method of claim 11, wherein the step of forming the metal layer comprises depositing a titanium and/or titanium nitride layer.

17. The method of claim 11, wherein the step of converting the metal layer into the silicide layer comprises a step of thermal processing.

18. The method of claim 11, wherein the step of converting the metal layer on the silicon substrate into the silicide layer also forms the silicide layer on a source/drain area on the silicon substrate.

19. The method of claim 11, further comprising a step of removing a portion of the silicide layer covering the spacer after the conversion of the metal layer into the silicide layer.

20. The method of claim 19, wherein the step of removing the portion of the silicide layer covering the spacer is to perform a step of wet etching.

21. The method of claim 19, further comprising a step of rapid thermal process after the removal of the portion of the silicide layer covering the spacer.
